(19) United States
(12) Patent Application Publication
(10) Pub. No.: US 2010/0167536 A1
(43) Pub. Date: Jul. 1, 2010

(54) METHOD FOR REMOVING HARDENED POLYMER RESIDUE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/643,911

(22) Filed: Dec. 21, 2009

(30) Foreign Application Priority Data
Dec. 29, 2008 (KR) 10-2008-0135925

(51) Int. Cl. H01L 21/768

(52) U.S. Cl. 438/669; 257/E21.582

(57) ABSTRACT

A method for efficiently removing hardened polymer residues generated in the process of forming metal lines. The method includes forming a metal layer over a lower film, forming a sacrificial protective film over the metal layer, forming a photosensitive pattern over the sacrificial protective film, forming a metal line by selectively etching the sacrificial protective film and the metal layer using the photosensitive pattern as a mask such that a residual sacrificial protective film is formed over the metal line, and then removing the residual sacrificial protective film from the metal line.

The present application claims priority under 35 U.S.C. §119 to Korean Patent Application No. 10-2008-0135925 (filed on Dec. 29), 2008, which is hereby incorporated by reference in its entirety.

### BACKGROUND

As high-integration of semiconductor devices and recent development in semiconductor fabrication techniques are rapidly made, the necessity for micronization and high precision of patterns formed on and/or over a substrate is gradually increasing. These trends also require micronization in the size of metal lines and a large number of techniques to decrease the size of metal lines are thus being researched. The micronization and high-precision of patterns cause a great decrease in pitch size, thereby leading to an increase in the number of chips arranged on and/or over a predetermined area of wafer and enabling manufacture of products with enhanced memory capabilities. Although the pitch sizes decrease, film depths do not considerably decrease, thereby disadvantageously increasing an aspect ratio between the linewidth and height. This problem also occurs in metal line formation processes as well as in the gate formation processes.

FIGS. 1A to 1B are sectional views illustrating a process for forming a semiconductor device. FIG. 1C is a sectional view illustrating a state in which hardened polymer residues are formed on and/or over a photoresist pattern.

As illustrated in FIG. 1A, metal layer 4 is formed on and/or over semiconductor substrate 2. Metal layer 4 may be a multi-layer that includes a first passivation layer composed of titanium and a second passivation layer composed of TiN as well as aluminium, copper or an aluminium/copper alloy. Photosensitive pattern 6 is then formed on and/or over metal layer 4.

As illustrated in FIG. 1B, photosensitive pattern 6 is then etched to form metal line 4a. In particular, polymer generation techniques are developed such that a polymer is intentionally formed on and/or over the sidewall of metal line 4a, while performing a photo or etching process during the patterning of metal line 4a to react the photoresist used for the photo-process with an etching gas. These polymer generation techniques aim to protect the sidewall of metal line 4a, causing generation of polymers during the etching process to form metal line 4a. However, the depth of metal line 4a increases as an aspect ratio increases, thereby limiting formation of the polymer up to the sidewall of the bottom of metal line 4a. To overcome this limitation, the amount of polymer may be increased.

As illustrated in FIG. 1C, hardened polymer residue 8 is disadvantageously formed on and/or over photoresist pattern 6. Furthermore, the removal of hardened polymer residue 8 in the subsequent cleaning process is also limited. When the thickness of the photoresist increases for the purpose of overcoming this limitation, the uniformity of the photoresist considerably decreases, thereby making it difficult to realize the desired pitch size.

### SUMMARY

Embodiments relate to a semiconductor technique such as a method for efficiently removing hardened polymer residues generated in the process of forming metal lines.

Embodiments relate to a method for efficiently removing hardened polymer residues generated on and/or over a photoresist pattern in the process of forming metal lines, while enhancing uniformity of the photoresist.

Embodiments relate to a method for efficiently removing hardened polymer residues generated on and/or over a photoresist pattern in the process of forming metal lines without increasing an amount of polymer to protect sidewalls of metal lines.

In accordance with embodiments, a method for removing hardened polymer residues can include at least one of the following: forming a metal layer on and/or over a lower film; forming a sacrificial protective film on and/or over the metal layer; forming a photosensitive pattern on and/or over the sacrificial protective film; selectively etching the sacrificial protective film and the metal layer using the photosensitive pattern to form a metal line; and then simultaneously removing the residual sacrificial protective film on and/or over the metal line and also hardened polymer residues formed on and/or over the residual sacrificial protective film.

In accordance with embodiments, the formation of the sacrificial protective film may be carried out by depositing a nitrogen-doped polymer to a thickness of several to several tens of nanometers on and/or over the metal layer by plasma enhanced chemical vapor deposition (PECVD).

In accordance with embodiments, a method for removing hardened polymer residues can include at least one of the following: forming a metal layer over a lower film; forming a sacrificial protective film over the metal layer; forming a photosensitive pattern over the sacrificial protective film; forming a metal line by selectively etching the sacrificial protective film and the metal layer using the photosensitive pattern as a mask such that a residual sacrificial protective film is formed over the metal line; and then removing the residual sacrificial protective film from the metal line.

In accordance with embodiments, a method for removing hardened polymer residues can include at least one of the following: forming a metal layer over a semiconductor substrate; forming a polymer film over the metal layer; forming a photoresist pattern over the polymer film; forming a metal line by selectively etching the polymer film and the metal layer such that residual polymers from the polymer film are formed on the metal line; and then removing the residual polymers from the metal line.

In accordance with embodiments, a method for removing hardened polymer residues can include at least one of the following: forming a metal layer over a semiconductor substrate; forming a polymer film over the metal layer; forming a photoresist pattern over the polymer film; forming a metal line by selectively etching the polymer film and the metal layer such that residual polymers from the polymer film are formed on the metal line; removing the residual polymers from the metal line; and then performing a cleaning process in order to remove additional residual polymers.

### DRAWINGS

FIGS. 1A to 1C illustrate a process for forming a metal line of a semiconductor device and hardened polymer residues formed on and/or over a photoresist pattern.

FIGS. 2A to 2B illustrate a method for efficiently removing hardened polymer residues generated on and/or over a photoresist pattern in the process of forming metal lines, in accordance with embodiments.

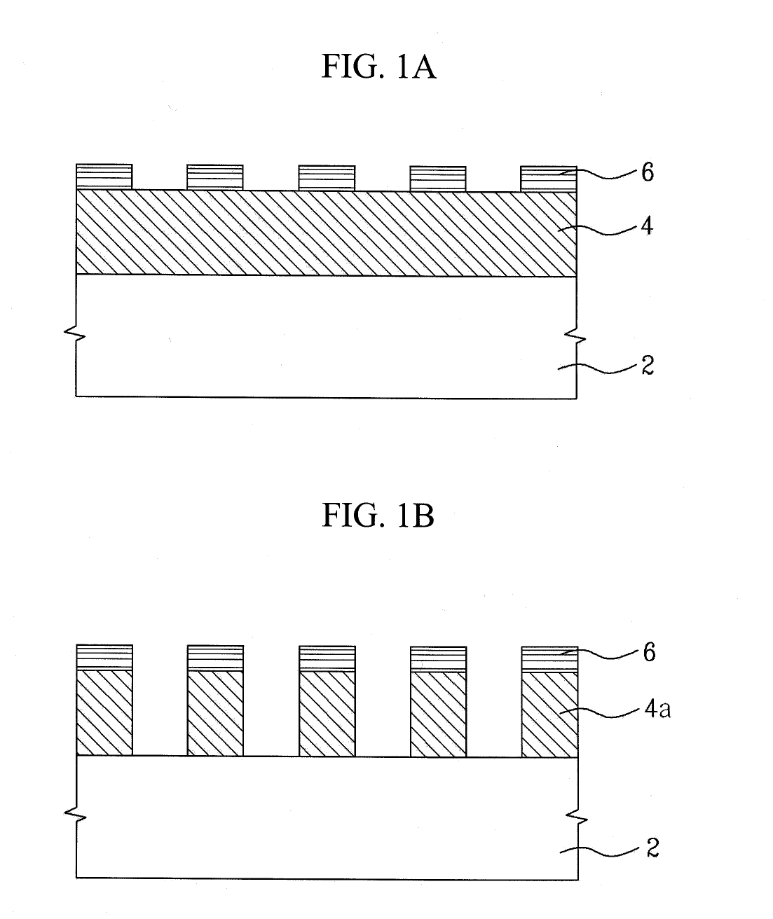

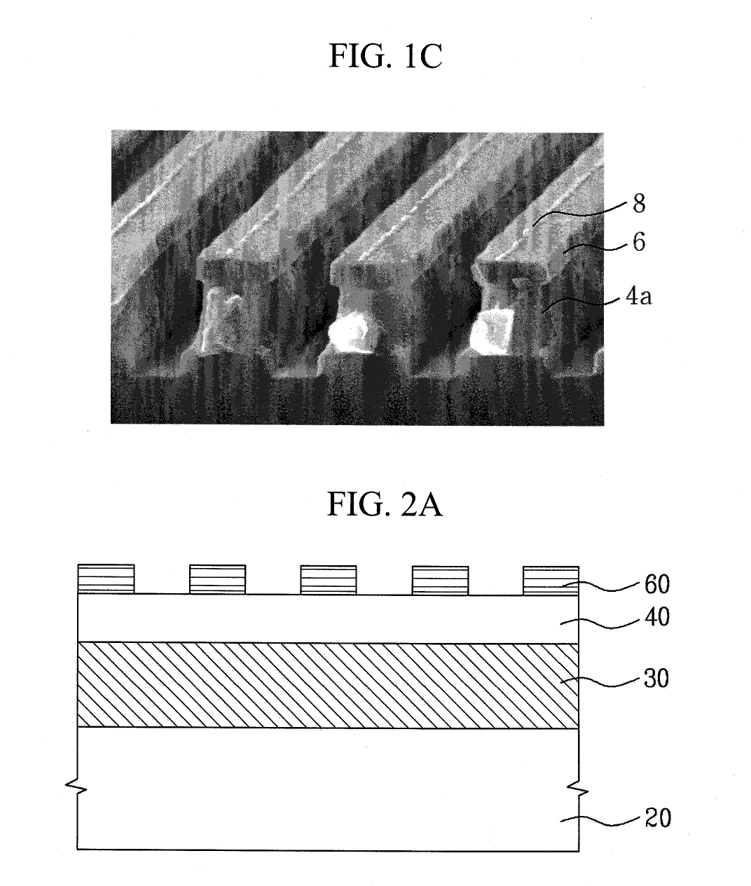

### DESCRIPTION

Other aspects, features and advantages of embodiments will be more clearly understood from the following detailed description taken in conjunction with the accompanying drawings.

Hereinafter, configurations and operations in accordance with embodiments will be described in detail with reference to the accompanying drawings. Although the configurations and functions of embodiments are illustrated in the accompanying drawings, in conjunction with at least one embodiment, and described with reference to the accompanying drawings and embodiments, the technical idea of embodiments and the important configurations and functions thereof are not limited thereto.

Hereinafter, a method for efficiently removing hardened polymer residues in accordance with embodiments will be illustrated with reference to the annexed drawings in detail.

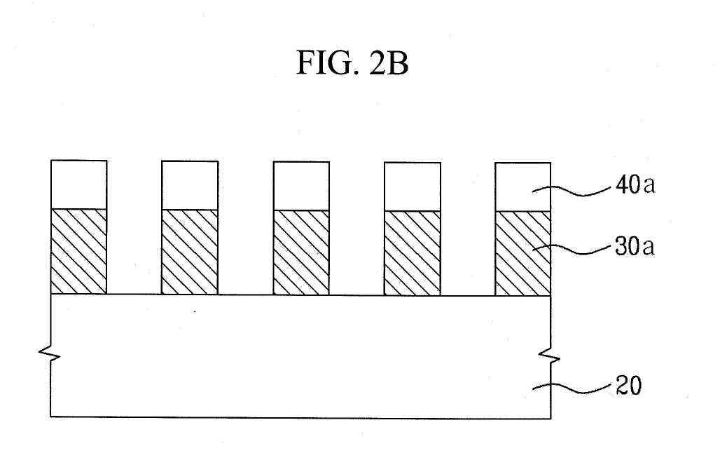

Example FIGS. 2A to 2B are sectional views illustrating a method for efficiently removing hardened polymer residues generated on and/or over a photoresist pattern in the process of forming metal lines.

As illustrated in example FIG. 2A, metal layer 30 is formed on and/or over semiconductor substrate 20. In accordance with embodiments, metal layer 30 may have a multi-layer structure. For example, metal layer 30 may include a first layer such as a passivation layer composed of titanium and a second layer such as a passivation layer composed of TiN and one of aluminum (Al), copper (Cu) or an aluminum/copper alloy thereof. Various dielectric films serving as anti-reflective films or protective films required for subsequent exposure or etching processes may be formed on and/or over metal layer 30.

Sacrificial protective film 40 is then formed on and/or over metal layer 30. Sacrificial protective film 40 is formed by depositing a nitrogen-doped polymer on and/or over metal layer 30 to a thickness in a range between several to several tens of nanometers. The deposition of nitrogen-doped polymer over metal layer 30 is carried out by plasma enhanced chemical vapor deposition (PECVD). The PECVD is carried out using nitrogen (N₂) and ammonia (NH₃) gases as well as benzene-ring precursors to deposit sacrificial protective film 40, and methylcyclohexane or ethylcyclohexane are used as the benzene-ring precursors. The deposition temperature used for PECVD is in a range between 60 to 80° C. Photosensitive pattern 60 is then formed on and/or over sacrificial protective film 40.

As illustrated in example FIG. 2B, metal line 30a is formed by selectively etching sacrificial protective film 40 and metal layer 30 using photosensitive pattern 60 as a mask. During the etching of sacrificial protective film 40, residual sacrificial protective film 40a is formed. The etching is carried out using reactive ion etching (RIE) and the reactive ion etching (RIE) is performed using plasma. Particularly, during the reactive ion etching, the photoresist material of photoresist pattern 60 reacts with the etching gas to form a polymer on and/or over metal line 30a to protect the sidewall of metal line 30a. In accordance with embodiments, during the reactive ion etching, photoresist pattern 60 is removed to form a polymer which protects the sidewall of metal line 30a. As a result, hardened polymer residues may be formed on and/or over residual sacrificial protective film 40a.

Subsequently, residual sacrificial protective film 40a may be removed from metal line 30a. In particular, removal of the residual sacrificial protective film 40a from the metal line 30a is carried out using oxygen (O₂) gas. The removal of residual sacrificial protective film 40a involves removal of the hardened polymer residues formed on and/or over residual sacrificial protective film 40a. Residual sacrificial protective film 40a is composed of C_{X}—N_{y} and reacts with oxygen (O₂) gas and is then removed, as depicted in the following reaction equation.

CₓN_{y}+O₂->CO₂+N₂↑

During removal of residual sacrificial protective film 40a, the polymer formed on and/or over the sidewall of metal line 30a during the reactive ion etching is also removed. Then, after removal of the polymer present on and/or over the sidewalls of residual sacrificial protective film 40a and metal line 30a, a cleaning process to remove the residual polymer residues is also performed. The cleaning process to remove the polymer residues is carried out using a solution containing deionized water and at least one of HF, H₂SO₄ and H₂O₂.

In accordance with embodiments, the nitrogen-doped polymer present on and/or over a metal layer is deposited to a thickness of several to several tens of nanometers (nm) and etched to form a metal line. Then, the nitrogen-doped polymer is removed, thus advantageously involving removal of the hardened polymer residues. As a result, the uniformity of the metal line is improved, thus realizing improvement in device reliability.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a metal layer over a lower film;
forming a sacrificial protective film over the metal layer;
forming a photosensitive pattern over the sacrificial protective film;
forming a metal line by selectively etching the sacrificial protective film and the metal layer using the photosensitive pattern as a mask such that a residual sacrificial protective film is formed over the metal line; and then
removing the residual sacrificial protective film from the metal line.

2. The method of claim 1, wherein forming the metal line comprises forming a polymer over the sidewall of the metal line during the selective etching of the sacrificial protective film and the metal layer.

3. The method of claim 2, wherein removing the residual sacrificial protective film comprises simultaneously removing polymers formed over the metal line.

4. The method of claim 3, further comprising, after simultaneously removing the residual sacrificial protective film and the polymer, performing a cleaning process in order to remove residual polymers.

5. The method of claim 4, wherein performing the cleaning process is done using a cleaning solution comprising deionized water and at least one of HF, H₂SO₄ and H₂O₂.

6. The method of claim 1, wherein forming the sacrificial protective film comprises depositing a nitrogen-doped polymer over the metal layer.

7. The method of claim 6, wherein the nitrogen-doped polymer is formed at a thickness in a range between several nanometers to several tens of nanometers.

8. The method of claim 7, wherein the nitrogen-doped polymer is deposited using plasma enhanced chemical vapor deposition (PECVD).

9. The method of claim 8, wherein the PECVD is performed using nitrogen (N₂) and ammonia (NH₃) gas and a benzene-ring precursor.

10. The method of claim 9, wherein the benzene-ring precursor comprises methylcyclohexane.

11. The method of claim 9, wherein the benzene-ring precursor comprises ethylcyclohexane.

12. The method according to claim 8, wherein the PECVD is performed at a temperature in a range between 60 to 80° C.

13. The method of claim 1, wherein removing the residual sacrificial protective film is performed by a plasma-treatment process.

14. The method of claim 13, wherein the plasma-treatment process uses oxygen (O₂).

15. The method of claim 14, wherein removing the residual sacrificial protective film comprises simultaneously removing hardened polymer residues formed over the residual sacrificial protective film.

17. A method comprising:
forming a metal layer over a semiconductor substrate;
forming a polymer film over the metal layer;
forming a photoresist pattern over the polymer film;
forming a metal line by selectively etching the polymer film and the metal layer such that residual polymers from the polymer film are formed on the metal line; and then removing the residual polymers from the metal line.

18. The method of claim 17, wherein polymer film comprises a nitrogen-doped polymer film.

19. The method of claim 17, wherein removing the residual polymer film is performed by a plasma-treatment process using oxygen (O₂).

20. A method comprising:
forming a metal layer over a semiconductor substrate;
forming a polymer film over the metal layer;
forming a photoresist pattern over the polymer film;
forming a metal line by selectively etching the polymer film and the metal layer such that residual polymers from the polymer film are formed on the metal line;
removing the residual polymers from the metal line; and then
performing a cleaning process in order to remove additional residual polymers.
